(19) United States
(12) Patent Application Publication
(10) Pub. No.: US 2011/0254545 A1
(43) Pub. Date: Oct. 20, 2011

(54) METHOD AND DEVICE FOR DETERMINING A MAGNETIC RESONANCE SYSTEM CONTROL SEQUENCE

(76) Inventors: MATTHIAS GEBHARDT, Erlangen (DE); DIETER RITTER, Furth (DE)

(21) Appl. No.: 13/087,258

(22) Filed: Apr. 14, 2011

(30) Foreign Application Priority Data
Apr. 15, 2010 (DE) 10 2010 015 044.4

(51) Int. Cl. G01R 33/44

(52) U.S. Cl. 324/307

(57) ABSTRACT

A method and a control sequence determination device for determining a magnetic resonance system control sequence are described. The magnetic resonance system control sequence includes a multichannel pulse train having a plurality of individual RF pulse trains that are to be transmitted in parallel by the magnetic resonance system over different independent radio-frequency transmit channels. The multichannel pulse train is calculated on the basis of a predefined target function with a predefined target magnetization in an RF pulse optimization method, where the target function is predefined such that the target function includes at least one local RF exposure value of an examination subject that is dependent on the control sequence. Also described are a method for operating a magnetic resonance system and a magnetic resonance system including the control sequence determination device.

This application claims the benefit of DE 10 2010 015 044.4, filed Apr. 15, 2010.

### BACKGROUND

The present embodiments relate to a method and a control sequence determination device for determining a magnetic resonance system control sequence.

In a magnetic resonance system, a body to be examined may be exposed to a relatively high main magnetic field of 3 or 7 Tesla, for example, with the aid of a main field magnet system. In addition, a magnetic field gradient is created with the aid of a gradient system. Radio-frequency excitation signals (RF signals) are transmitted via a radio-frequency transmission system using suitable antenna devices. Nuclear spins of specific atoms are resonantly excited by the radio-frequency field being tilted in a spatially resolved manner by a defined flip angle relative to the magnetic field lines of the main magnetic field. This radio-frequency excitation or the resulting flip angle distribution is also referred to in the following as nuclear magnetization or “magnetization” for short. During the relaxation of the nuclear spins, radio-frequency signals (e.g., magnetic resonance signals) are emitted, the radio-frequency signals being received by suitable receive antennas and being processed further. The desired image data may be reconstructed from the raw data acquired in this way. The transmission of the radio-frequency signals for nuclear spin magnetization is accomplished by a “whole-body coil” (e.g., “bodycoil”) or by local coils mounted adjacent to or on the patient or subject. A typical design of the whole-body coil is a cage-like antenna (e.g., birdcage antenna) that consists of a plurality of transmit rods arranged running parallel to the longitudinal axis around a patient space of a tomography apparatus, in which the patient is located during the examination. On an end face, the antenna rods are connected to one another in a ring shape.

In the prior art, whole-body antennas may be operated in a “homogeneous mode,” (e.g., a “CP mode”). For this purpose, a single temporal RF signal is applied to all components of the transmit antenna (e.g., all the transmit rods of a birdcage antenna). The pulses may be passed on to the individual components phase-shifted by a shift matched to the geometry of the transmit coil. For example, in a birdcage antenna having 16 rods, the rods may be activated and controlled offset using the same RF magnitude signal with a 22.5° phase shift. The homogeneous excitation leads to the patient being exposed to a global radio-frequency dose that must be limited according to the conventional rules, since an excessively high radio-frequency exposure may lead to the patient being harmed. For this reason, the radio-frequency exposure of the patient may be calculated in advance during the planning of the radio-frequency pulses to be emitted, and the radio-frequency pulses are chosen such that a specific limit is not reached. In this context, the RF exposure may be a physiological exposure induced by the RF irradiation and not the introduced RF energy. A typical measure for the radio-frequency exposure is the specific absorption rate (“SAR”) value that specifies in watts/kg the biological exposure acting on the patient due to a specific radio-frequency pulse power. For example, a standardized limit of 4 watts/kg applies to the global SAR or RF exposure of a patient in the “first level,” according to the IEC standard. In addition, apart from the advance planning, the SAR exposure of the patient during the examination is continuously monitored by suitable safety devices on the magnetic resonance system, and a measurement is modified or aborted if the SAR value exceeds the prescribed standards. The planning is conducted in a precise manner in advance in order to avoid a measurement being aborted, since the aborted measurement would make it necessary to perform a new measurement.

In newer-generation magnetic resonance systems, individual RF signals adapted to the imaging may be applied to the individual transmit channels (e.g., the individual rods of the birdcage antenna). A multichannel pulse train that includes a plurality of individual radio-frequency pulse trains, which may be transmitted in parallel over different independent radio-frequency transmit channels, is transmitted. The multichannel pulse train (e.g., a “pTX pulse” on account of the parallel transmission of the individual pulses) may be used, for example, as an excitation, refocusing and/or inversion pulse.

The multichannel pulse trains may be generated in advance for a specific planned measurement. The individual RF pulse trains (e.g., the RF trajectories) for the individual transmit channels are determined over time in an optimization method as a function of a “transmission k-space gradient trajectory,” which may be predefined by a measurement protocol. The “transmission k-space gradient trajectory” (referred to in the following as “k-space gradient trajectory” or “gradient trajectory”) is the coordinates in the k-space that are reached at specific times by setting the individual gradients (e.g., using gradient pulse trains (with appropriate x-, y- and z-gradient pulses) to be transmitted in a coordinated manner appropriate for the RF pulse trains). The k-space is the spatial frequency domain, and the gradient trajectory in the k-space describes on which path the k-space will be traversed in time when the RF pulse or the parallel pulses is or are transmitted by corresponding switching of the gradient pulses. By setting the gradient trajectory in the k-space (e.g., by setting the appropriate gradient trajectory applied in parallel with the multichannel pulse train), at which spatial frequencies specific RF energies are deposited may be determined.

The optimization method operates with a predefined target function. For the planning of the RF pulse sequence, the user specifies a target magnetization (e.g., a desired flip angle distribution) that is used as a reference value within the target function. In the optimization program, the appropriate RF pulse sequence for the predefined target function is calculated for the individual channels such that the target magnetization is reached. A method for developing such multichannel pulse trains in parallel excitation methods is described, for example, in W. Grishom et al., “Spatial Domain Method for the Design of RF Pulses in Multicoil Parallel Excitation,” Mag. Res. Med. 56, pp. 620-629, 2006.

For a specific measurement, the different multichannel pulse trains, the gradient pulse trains belonging to the respective control sequence, and further control parameters are defined in a measurement protocol that is produced in advance and, for example, retrieved from a memory for a specific measurement and may be modified by the operator on site. During the measurement, the magnetic resonance system is controlled fully automatically on the basis of the measurement protocol, where the control device of the magnetic resonance system reads out the commands from the measurement protocol and processes the commands.

During the transmission of multichannel pulse trains, the previously homogeneous excitation may be replaced in the measurement space and consequently also in the patient by an essentially arbitrarily shaped excitation. In order to estimate the maximum radio-frequency exposure, every radio-frequency superposition may be examined. This may be investigated, for example, on a patient model by including typical tissue properties such as conductivity, dielectricity, and density in a simulation. It is already known from previously performed simulations that “hotspots” may be formed in the radio-frequency field in the patient. At the hotspots, the radio-frequency exposure may account for a multiple of the values previously known from homogeneous excitation. The radio-frequency limitations resulting therefrom are unacceptable for the performance of clinical imaging, since, taking the hotspots into account, the total transmit power would be too low for generating acceptable images. Therefore, the radio-frequency exposure is to be reduced when the multichannel pulse trains are transmitted.

### SUMMARY AND DESCRIPTION

The present embodiments may obviate one or more of the drawbacks or limitations in the related art. For example, a method and a corresponding control sequence determination device for determining magnetic resonance system control sequences that reduce and/or allow safer and more reliable controllability of local radio-frequency exposure of a patient during development of multichannel pulse trains may be provided.

In a method according to the present embodiments, a multichannel pulse train is calculated in an RF pulse optimization method on the basis of a predefined target function with a predefined target magnetization.

According to the present embodiments, a target function is predefined such that the target function includes at least one local RF exposure value of an examination subject that is dependent on the control sequence (or on the multichannel pulse train). Because the local RF exposure value is dependent on the control sequence, the local RF exposure value forms a “local exposure function term” within the target function. The terms “local RF exposure value” and “local exposure function term” are used synonymously in the following description. A local RF exposure may not be the RF amplitude occurring at a location or in a specific volume unit, but may be the energy load resulting therefrom or the physiological exposure induced by the RF irradiation (e.g., in the form of a specific energy dose (“SED”) value or a specific absorption rate (“SAR”) value in a specific local volume (e.g., at one or more hotspots)). The local RF exposure value used in the target function may be based on one or more local SAR values or SED values, for example.

The RF exposure (e.g., not just a global RF exposure) at individual spatial locations is considered in the target function. By including the local RF exposure value in the target function, during the optimization, the local RF exposure does not become too high and/or specific conditions are fulfilled so that the local RF exposure may be more easily controlled and monitored subsequently in a use of the control sequence during a data acquisition. This is dependent on the form, in which the local exposure function term is constructed in the target function.

Accordingly, a control sequence determination device according to the present embodiments includes an input interface for acquiring a target magnetization and an RF pulse optimization unit for calculating a multichannel pulse train on the basis of a predefined target function with a predefined target magnetization in an RF pulse optimization method. The control sequence determination device also includes a control sequence output interface for passing on the control sequence for controlling the magnetic resonance system for the data acquisition to a control device or for storing it in a memory for that purpose. In one embodiment, the control sequence determination device is configured such that in the RF pulse optimization method, the control sequence determination device uses a target function that includes at least one local RF exposure value of an examination subject that is dependent on the control sequence.

In one embodiment of a method for operating a magnetic resonance system, a control sequence is determined according to the above-described method, and the magnetic resonance system is operated using the control sequence. Accordingly, a magnetic resonance system of the present embodiments has a control sequence determination device as described above.

Components of the control sequence determination device (e.g., an RF pulse optimization unit and an RF exposure optimization unit) may be in the form of software components in non-transistory storage media and implemented by a processor. The input interface may be, for example, a user interface allowing manual input of a target magnetization (e.g., a graphical user interface). The input interface may also be an interface for selecting and transferring data (e.g., a suitable target function) from a data memory arranged inside the control sequence determination device or connected to the control sequence determination device via a network (e.g., using the user interface). The control sequence output interface may be, for example, an interface that transmits the control sequence to a magnetic resonance controller in order to control the measurement directly with the control sequence. Alternatively, the control sequence output interface may be an interface that sends the data over a network and/or stores the data in a memory for later use. These interfaces may also be, at least partially, in the form of software and may make use of hardware interfaces of an existing computer.

The present embodiments also include a computer program that may be loaded directly into a non-transitory memory of a control sequence determination device, the computer program including program code sections for performing all the acts of the methods discussed above when the program is executed in the control sequence determination device. Such a software-based implementation has the advantage that prior art devices that are used for determining control sequences (e.g., suitable computers in data centers of the magnetic resonance system manufacturers) may also be modified in a suitable fashion by implementation of the program in order to determine, in the manner according to the present embodiments, control sequences that are associated with a lower and/or more reliably and safely controllable radio-frequency exposure.

The local RF exposure is different at different locations in the body of the examination subject. Hotspots, at which particularly high RF exposures (e.g., RF-induced physiological exposures) occur, may form.

The local RF exposure value may be formed from a combination of different local RF exposure values in different volume units having specific tissue properties. The volume units may be individual volume elements (e.g., individual voxels) or larger volume units (e.g., entire voxel groups). In one embodiment, the local RF exposure value is based on a local RF exposure vector that includes the local RF exposure values. The local RF exposure vector may include a defined number of local RF exposure values at particularly exposed positions (e.g., at previously identified potential hotspots). For example, the local RF exposure values of a specific number of the most severely exposed hotspots (e.g., the 30 strongest hotspots) may be used to construct a local RF exposure vector.

The local RF exposure value used within the target function (e.g., the local exposure function term) may include a predefined norm of the local RF exposure vector. Different possible norms are, for example, the maximum norm, an absolute column sum norm (L norm) or a Euclidian norm (L₂ norm).

In one embodiment, the target function or the local exposure function term is chosen such that the local RF exposure value is minimized in the optimization method.

In one embodiment, a maximum value of the local RF exposure may be minimized in the optimization method. For example, if the local exposure function term contains the maximum norm of the local RF exposure vector, the maximum vector element of the local RF exposure vector is minimized automatically. This is the hotspot exhibiting the strongest exposure, for example. With this simple variant, however, only one local hotspot is taken into account, and not a combination of different local RF exposure values in different volume units.

In another embodiment, the target function is chosen such that a predefined combination, for example a sum, of spatially different RF exposure values is minimized in the optimization method. This may be realized, for example, in that an absolute column sum norm or a Euclidean norm of the local RF exposure vector is used as the local RF exposure value in the target function.

The local exposure function term, therefore, forms a local exposure compensation term that leads to the multichannel pulse trains being calculated in such a way in the optimization of the target function that particularly critical local RF exposure values are reduced and not so critical local RF exposure values are increased as necessary. If, for example, an RF exposure vector is chosen for the local exposure function term from the local RF exposure values at the different hotspots, a type of “hotspot equalization term” is introduced into the target function for the pTX pulse design. RF energy is withdrawn from one or a small number of critical hotspots in the RF exposure vector, and RF energy is supplied accordingly to the other not so critical hotspots.

With realistically achievable magnetizations, the local SED exposure may be reduced by a factor of four compared to an optimization using a conventional target function.

In one embodiment of the method for determining magnetic resonance system control sequences, the target function is chosen such that the target function is dependent on a deviation of a local RF exposure value from a global RF exposure value. The local RF exposure value is not minimized as described above, but the ratio of the local RF exposure value to a global RF exposure value is optimized to a predefined value in the optimization method. The local RF exposure value may be multiplied, for example, by a predefined deviation factor, and the difference of the value obtained from the predefined global RF exposure value is minimized within the target function within the scope of the optimization method.

The global RF exposure value may be a value such as, for example, a conventional SAR value that may be monitored in the conventional way during a measurement with respect to compliance with a limit value. For example, the limit value may be the value of 4 W/kg in the “first level” according to the IEC standard. Different methods for taking into account the global RF exposure during the planning prior to a measurement and monitoring the global RF exposure during a measurement (e.g., using a radio-frequency power monitoring device such as a radio frequency safety watch dog (“RFSWD”)) are known to the person skilled in the art and therefore are not explained in further detail here.

An advantage of this method is that in the course of the pulse design, there is no minimization in an arbitrary form to a relatively undefined local exposure function term, in which it is not clear at the time of calculating the RF pulses whether the sequence later used (at the desired transmit power and possibly using a multilayer recording method) would violate the local limit values or not. Instead, using the optimization to the fixed ratio between the local RF exposure value and the global RF exposure value, there is no longer any difference in the mechanism for predicting the global RF exposure and the local RF exposure. The global RF exposure is relatively effectively calculable in advance using the previous methods. A further advantage of this method is that local exposure values are not reduced unnecessarily, since a minimization of the local RF exposure is automatically associated with a lower RF amplitude and consequently with lower data acquisition performance. Overall, the local RF exposure may be controlled more accurately, and compliance with the limit values monitored and an improvement in image quality are achieved.

The local RF exposure value may be based on a specific energy dose of at least one volume unit (e.g., an individual voxel or a voxel group).

In one embodiment of the method for determining magnetic resonance system control sequences, the local RF exposure value is based on a correlation (e.g., a cross-correlation) of the individual RF pulse trains of the multichannel pulse train that are to be transmitted in parallel. The local RF exposure value may also be based on a tissue-specific sensitivity matrix that, for different volume units of the examination subject, represents the dependence of the RF exposure on a current RF transmission amplitude in the respective volume unit. For each individual voxel, the sensitivity matrix may contain, for example, a sensitivity value that, when multiplied by the amplitude of the radio-frequency field, specifies the E-field in the respective voxel.

In another embodiment of the method for determining magnetic resonance system control sequences, the k-space gradient trajectory is also optimized in terms of the local RF exposure value using a parameterizable function in an RF exposure optimization method. The multichannel pulse trains were previously determined in the optimization method as a function of a fixed “k-space gradient trajectory,” which may be predefined by a measurement protocol. In the construction of the gradient trajectory, the relevant areas in the k-space are also traversed. For example, when a sharply delimited region (e.g., a rectangle or oval) is to be excited in the position space, the k-space is also well covered in an outer limit region. If an unsharp delimitation is desired, coverage in an inner k-space region is sufficient. A protocol developer may bring a certain experience to bear when selecting the k-space trajectory in order that the target magnetization may be achieved.

In one embodiment of the method for determining magnetic resonance system control sequences, the measurement protocol developer may specify a k-space gradient trajectory (e.g., an initial basic form of the k-space gradient trajectory). In other words, the gradient trajectory may be chosen within the framework of a predefined basic form in the optimization method such that the RF energy is distributed as widely as possible in the k-space in order to avoid high RF peaks. The occurring RF peaks may increase the effective total radio-frequency power, which dominates the SAR exposure of the patient. The radio-frequency exposure may be reduced for the patient in a simple manner by almost a factor of three while maintaining the same image quality.

In one embodiment, the control sequence determination device is configured to optimize the k-space gradient trajectory in an RF exposure optimization method using a parameterizable function at least with respect to an RF exposure value of the examination subject.

Geometry parameters of the k-space gradient trajectory are minimized in this case (within the RF exposure optimization method). The geometry parameters may include parameters for determining the geometry design of echo-planar imaging (“EPI”) trajectories and/or spoke positions and/or spiral geometries and/or radial geometries and/or free-form geometries.

For example, the gradient trajectory may be predefined as a spiral with variable parameters, where the original linear increase in size of the radius in an Archimedean spiral may be variably adjusted using a function (e.g., a 2-point spline). The propagation of the spiral in the x-direction and y-direction as well as the spacing between two adjacent tracks within the spiral may be influenced by the variable geometry parameters.

In a spoke geometry in the k-space, individual points in the k-space are reached by setting x and y gradients (e.g., ten points that lie on a plurality of circles). In order to hold a reached x/y position in the k-space, the x-gradient and the y-gradient are suspended (e.g., no more pulses are applied in the x-gradient and y-gradient direction). Instead, a z-gradient is switched during the transmission of the radio-frequency pulses in order to measure the relevant location in the k-space in a layer-selective manner. In such a measurement method, the x and y positions of the “spokes” may be specified in the k-space by suitable choice of the geometry parameters. Radial geometries may be, for example, rosette geometries, and free-form geometries are freely selectable geometries.

The RF exposure optimization method may be linked with the RF pulse optimization method. In other words, the RF exposure optimization method and the RF pulse optimization method are integrated into each other in some way (e.g., the RF exposure optimization method incorporates the RF pulse optimization method or vice versa).

In one embodiment of the method for determining magnetic resonance system control sequences, an iterative method is performed in that a multichannel pulse train is determined for a given k-space gradient trajectory using the RF pulse optimization method. The iterative method may be performed, for example, using the above-described conventional RF pulse optimization method using the target function according to the present embodiments (e.g., the actual magnetization is adjusted to a target or reference magnetization using a least-mean-square method through variation of the RF pulse trains that are to be transmitted). In a further act of the iterative method, a provisional RF exposure of the examination subject is determined on the basis of the determined multichannel pulse train. In other words, the RF pulses predefined within the multichannel pulse train and the predefined gradient trajectory (or the gradient pulses defined thereby) are inserted into a simulation, and the RF exposure is calculated. The geometry parameters of the k-space gradient trajectory are varied in a further act in accordance with a predefined optimization strategy of the RF exposure optimization method in order to reduce the RF exposure. The aforementioned acts are repeated with the new k-space gradient trajectory in further iteration steps. This process continues until such time as an abort criterion is reached (e.g., until a maximum number of iteration steps has been executed or the target function that is to be minimized has reached the desired minimum or has dropped below a predefined a value).

The calculation of the multichannel pulse train is performed within the framework of the RF pulse optimization method according to the present embodiments initially for a lower target magnetization. The multichannel pulse train determined in the process is subsequently scaled up to a definitive target magnetization and, if necessary, adaptively corrected once more. For this approach, use is made of the fact that for small magnetizations (e.g., for small flip angles (in the “low-flip domain”) between 0 and 5°), the magnetization behavior is still linear. In the low-flip domain, a calculation using an optimization method is therefore considerably easier and more stable. Once the optimal multichannel pulse train for the low-flip domain has been found, upscaling is possible without difficulty in a following act. If, for example, the calculation is performed in the low-flip domain for a flip angle of maximum α=5°, and the actual magnetization is to take place at a flip angle α of maximum 90°, then according to the ratio of the flip angles, the amplitude values of the RF pulses may be multiplied by a factor of 18. The errors occurring in the process may subsequently be determined and corrected in the course of a (Bloch) simulation.

If a target function is used in these following acts, the target function has a corresponding local RF exposure value of the examination subject (e.g., a local exposure function term).

Further parameters may also be optimized in terms of an RF exposure value of the examination subject within the framework of the RF exposure optimization method. For example, the parameters used for the RF pulse optimization within the Thikonov regularization or also other system parameters such as, for example, the maximum gradient strength or a “slew rate” (e.g., a rise time of the gradient pulses) may be varied in the course of the optimization in order to achieve even better results.

### BRIEF DESCRIPTION OF THE DRAWINGS

FIG. 1 shows a schematic representation of one embodiment of a magnetic resonance system;

FIG. 2 shows a flowchart for one embodiment of a method for determining a magnetic resonance system control sequence;

FIG. 3 is a depiction of different L-curves that show a root-mean-square deviation of a flip angle as a function of a local SED value; and

FIG. 4 shows graphs of two possible local exposure function terms that are dependent on a ratio of a local RF exposure value to a global RF exposure value.

### DETAILED DESCRIPTION OF THE DRAWINGS

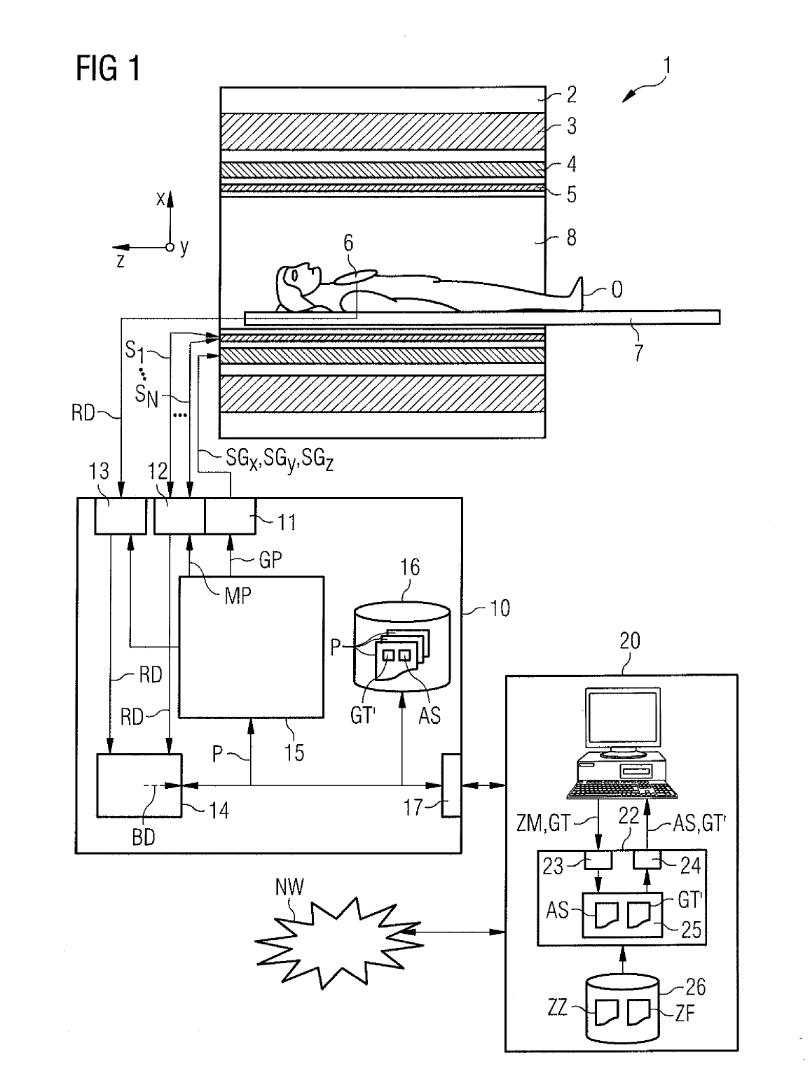

FIG. 1 shows one embodiment of a magnetic resonance system 1. The magnetic resonance system 1 includes a magnetic resonance scanner 2 with an examination space 8 or patient tunnel 8 contained within the magnetic resonance scanner 2. A patient couch 7 (e.g., a patient bed) may be moved into the patient tunnel 8 so that a patient O or subject lying on the patient couch 7 may be placed at a specific position inside the magnetic resonance scanner 2 relative to a magnet system and a radio-frequency system disposed within the magnet system during an examination. Alternatively, the patient couch 7 (and the patient O lying on the patient couch 7) may also be moved between different positions during a measurement.

Components of the magnetic resonance scanner 2 may include a main field magnet 3, a gradient system 4 having magnetic field gradient coils for applying arbitrary magnetic field gradients in the x-, y- and z-direction, and a whole-body radio-frequency coil 5. Magnetic resonance signals induced in the examination subject O may be received by the whole-body coil 5, such that the radio-frequency signals for inducing the magnetic resonance signals are also transmitted. In one embodiment, the MR signals may be received by local coils 6 placed, for example, on or under the examination subject O. These components of the magnetic resonance scanner 2 may be known to the person skilled in the art and therefore, are depicted only in roughly schematic form in FIG. 1.

In one embodiment, the whole-body radio-frequency coil 5 is constructed in the form of a birdcage antenna and has a number N of individual antenna rods (e.g., a plurality of individual antenna rods) that run parallel to the patient tunnel 8 and are arranged uniformly distributed on a circumference around the patient tunnel 8. At an end side, the plurality of individual antenna rods is capacitively connected in a ring shape.

Each individual antenna rod of the plurality of individual antenna rods may be activated separately as individual transmit channels S₁-S_{N} by a control device 10. The control device 10 may be a control computer that may also include a plurality of individual computers (e.g., where appropriate, also physically separated from one another and interconnected via suitable cables). The control device 10 is connected via a terminal interface 17 to a terminal 20, through which an operator may control the magnetic resonance system 1. In the embodiment shown in FIG. 1, the terminal 20 includes a computer equipped with a keyboard, one or more screens and further input devices such as, for example, a mouse, such that a graphical user interface is available to the operator.

The control device 10 includes, among other components, a gradient control unit 11 that may consist of a plurality of subcomponents. Control signals SGₓ, SG_{y}, SG_{z} are connected to individual gradient coils via the gradient control unit 11. The control signals SGₓ, SG_{y}, SG are gradient pulses that are set during a measurement at precisely designated positions in time and with a precisely predefined time characteristic.

The control device 10 also has a radio-frequency transmit/receive unit 12. The RF transmit/receive unit 12 includes a plurality of subcomponents for the purpose of applying radio-frequency pulses separately and in parallel to the individual transmit channels S₁-S_{N} (e.g., to the individually controllable antenna rods of the bodycoil). The magnetic resonance signals may also be received via the transmit/receive unit 12. In one embodiment, the magnetic resonance signals may be received with the aid of the local coils 6. Raw data RD received by the local coils 6 is read out and processed by an RF receive unit 13. The magnetic resonance signals received from the local coils 6 or from the whole-body coil using the RF transmit/receive unit 12 are passed on as the raw data RD to a reconstruction unit 14 that reconstructs image data BD from the raw data RD and stores the image data BD in a memory 16 and/or transfers the image data BD via the interface 17 to the terminal 20 so that the image data BD may be studied by the operator. The image data BD may also be stored and/or displayed and analyzed at other locations via a network NW.

The gradient control unit 11, the radio-frequency transmit/receive unit 12 and the receive unit 13 for the local coils 6 may each be controlled in a coordinated manner by a measurement control unit 15. The measurement control unit 15 provides, by corresponding commands, that a desired gradient pulse train GP is transmitted using suitable gradient control signals SGₓ, SG_{y}, SG_{z} and in parallel, controls the RF transmit/receive unit 12 such that a multichannel pulse train MP is transmitted (e.g., the appropriate radio-frequency pulses are applied in parallel to the individual transmit rods of the whole-body coil 5 on the individual transmit channels S₁, -S_{N}). The magnetic resonance signals at the local coils 6 are read out and processed further by the RF receive unit 13 at the appropriate time instant, or any signals at the whole-body coil 5 are read out and processed further by the RF transmit/receive unit 12. The measurement control unit 15 specifies the corresponding signals (e.g., the multichannel pulse train MP) to the radio-frequency transmit/receive unit 12 and the gradient pulse train GP to the gradient control unit 11 in accordance with a predefined control protocol P. All the control data that is set during a measurement is stored in the control protocol P.

In one embodiment, a plurality of control protocols P for different measurements is stored in a memory 16. The plurality of control protocols P may be selected by the operator via the terminal 20 and varied in order to have an appropriate control protocol P, with which the measurement control unit 15 may work, available for the currently desired measurement. The operator may also retrieve the plurality of control protocols P, for example, from a manufacturer of the magnetic resonance system 1, via a network NW and modify and use the plurality of protocols P as necessary.

The basic execution sequence of such a magnetic resonance measurement and the components for the control of the magnetic resonance measurement are well-known to the person skilled in the art, so they will not be discussed in further detail here. The magnetic resonance scanner 2 and the associated control device 10 may also have a plurality of further components that are not explained in detail here.

The magnetic resonance scanner 2 may be constructed differently (e.g., with a patient space that is open at the sides and with the radio-frequency whole-body coil not built as a birdcage antenna). The magnetic resonance seamier 2 includes the plurality of separately controllable transmit channels S₁-S_{N} and accordingly, a corresponding number of channel controllers are also available in the control device 10 using the radio-frequency transmit/receive unit 12 in order to enable the individual transmit channels S₁-S_{N} to be activated and controlled separately.

FIG. 1 also shows one embodiment of a control sequence determination device 22 that determines a magnetic resonance system control sequence AS. The magnetic resonance system control sequence AS includes a predefined multichannel pulse train MP for controlling the individual transmit channels S₁-S_{N} for a specific measurement. In the embodiment shown in FIG. 1, the magnetic resonance system control sequence AS is produced as part of the measurement protocol P.

The control sequence determination device 22 is shown as part of the terminal 20 and may be realized in the form of software components on the computer of the terminal 20 (e.g., computer). The control sequence determination device 22 may also be implemented as part of the control device 10 or on a separate computing system, and the finished control sequences AS are transmitted (e.g., also within the framework of a complete control protocol P) over a network NW to the magnetic resonance system 1.

The control sequence determination device 22 has an input interface 23. Via the input interface 23, the control sequence determination device 22 receives a target magnetization ZM that specifies how a flip angle distribution should be in the desired measurement. A k-space gradient trajectory GT is also predefined.

The target magnetization ZM and the k-space gradient trajectory GT are provided, for example, by an expert suitably qualified for developing control protocols for specific measurements. The data thus obtained is passed on to an RF pulse optimization unit 25 that automatically generates a specific control sequence AS with an optimal multichannel pulse train MP for achieving the desired target magnetization ZM. In one embodiment of the method, the k-space gradient trajectory GT (“gradient trajectory”) is also modified (i.e., a modified gradient trajectory GT′ is generated). The modified gradient trajectory GT′ is output via a control sequence output interface 24 and may be passed on to the control device 10 (e.g., within the framework of a control protocol P, in which further specifications for controlling the magnetic resonance system 1 are defined (e.g., parameters for reconstructing the images from the raw data)).

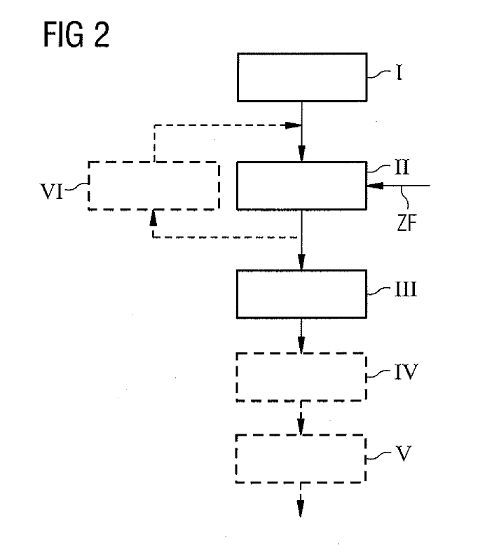

A method for determining the magnetic resonance system control sequence AS is explained below with the aid of an example and with reference to the flowchart according to FIG. 2.

In act I, the target magnetization ZM and the gradient trajectory GT are predefined. In other words, a gradient pulse sequence for traveling along the gradient trajectory GT is defined.

In act II, the design of the multichannel pulse trainer takes place automatically. The individual RF pulse sequences are developed for the different transmit channels (e.g., which RF pulse shape is transmitted on which channel is precisely calculated). This is carried out initially for a “low-flip domain” (e.g., having flip angles under 5°), since in the low-flip domain, the magnetization behavior still runs in linear fashion. An iterative optimization method may be used. In one embodiment, a finite-difference method may be used. Other optimization methods including, for example, non-iterative optimization methods may also be employed. With the previously known method, the optimization method is performed such that, for example, a mean square deviation (least-mean-square) between the target magnetization and the actual magnetization is minimized. In other words, the following solution is sought:

b=arg_{b}min(∥m_{actual}−m_{target}∥²)=arg_{b}min(∥A·b−m_{target}∥²) (1)

In equation (1), m_{actual}=A·b is the actual magnetization, where A is the design matrix and b is the vector of the RF curves b_{c}(t) to be transmitted in parallel. m_{target} is the target magnetization. If the solution to equation (1) is found, a function b_{c}(t) of the amplitude as a function of the time for all transmit channels present is yielded as the result (i.e., N functions are obtained (one function b_{c}(t) for each channel c=1 to N)).

In many methods, an extension of the target function is used in the form of the Thikonov regularization, with which solutions for b_{c}(t) that contain the smallest possible RF amplitude values are preferred because the voltages are included squared in the calculation of the output power. A target function according to equation (1) extended by the Thikonov regularization then is as follows:

b=arg_{b}min(∥a·b−m_{target}∥²+β²∥b∥²) (2)

The factor β is the Thikonov parameter, through the setting of which a tradeoff may be achieved between the homogeneity of the flip angle and a large SAR.

According to the present embodiments, a target function ZF is predefined for act II. The target function ZF contains a local exposure function term f(SED_{loc}) in addition or alternatively to the Thikonov regularization:

b=arg_{b}min(∥A·b−m_{target}∥²+β²∥b∥²+γf(SED_{loc})) (3)

In equation (3), the value γ is a weighting factor used to find an optimum (or an adjustable weighting) between the achievable homogeneity of the magnetization and the maximum local SED value. SED_{loc} is the local exposure vector of the local SED values SED_{loc,h} (in [W/kg]). The local SED values SED_{loc,h} at a hotspot h in the body of the examination subject O may be calculated using the following equation:

$${SED}_{loc , h} = 0.5 \cdot real ( {\sum }_{j = 1}^{N} {\sum }_{k = 1}^{N} {ZZ}_{hjk} \cdot {T}_{sum , jk} ) \cdot \frac{1}{{ρ}_{h}} \qquad ( 4 )$$

N is the number of independent transmit channels. ρₕ is the density of the patient at the hotspot h in kg/m³ and j and k are control variables that run from 1 to N. The values ZZₕⱼₖ are individual elements of a sensitivity matrix ZZ. In equation (4), the sensitivity matrix ZZ contains, for each hotspot h, a sensitivity value which, when multiplied by the amplitude of the RF field, represents the E-field in the hotspot and consequently forms a conversion factor from the amplitude of the radio-frequency curve to the actual energetic exposure in the hotspot. In other words, if 30 hotspots have been identified, the local RF exposure vector SED_{loc} consists of 30 vector elements according to equation (4).

T_{sum,jk} is the cross-correlation of the RF curves of the RF pulse train:

$${T}_{sum , jk} = Δ t \cdot {\sum }_{c = 0}^{N} conj ( {b}_{c}^{′} ) \cdot {b}_{c} \qquad ( 5 )$$

Δt is the sampling interval in s. The cross-correlation indicates whether the RF curves of the RF pulse train are amplified or reduced at a specific location during the superposition.

The sensitivity matrix ZZ and the target function may be stored, for example, in a memory 26 of the control sequence determination device 22 and retrieved from there as necessary. The sensitivity matrix ZZ may be determined, for example, in advance using simulations on human body models. A method for determining the sensitivity matrix ZZ and the local SED values SED_{loc,h} is described, for example, in DE 10 2009 024 077. Different sensitivity matrices ZZ may also be stored for different body types (e.g., patients of different sizes).

The local exposure function term f(SED_{loc}) in equation (3) may be embodied in different ways.

For example, the local exposure function term f(SED_{loc}) may be the squared maximum norm max²(SED_{loc}). This results in the critical maximum of the local SED vector (e.g., the biggest hotspot) being minimized.

In another embodiment, f(SED_{loc})=∥SED_{loc}∥² is set. This leads to RF energy being withdrawn from more critical hotspots in the list and energy being supplied to other less critical hotspots, since during the optimization, a minimization of the squared distance of the local SED vector from the zero point is achieved.

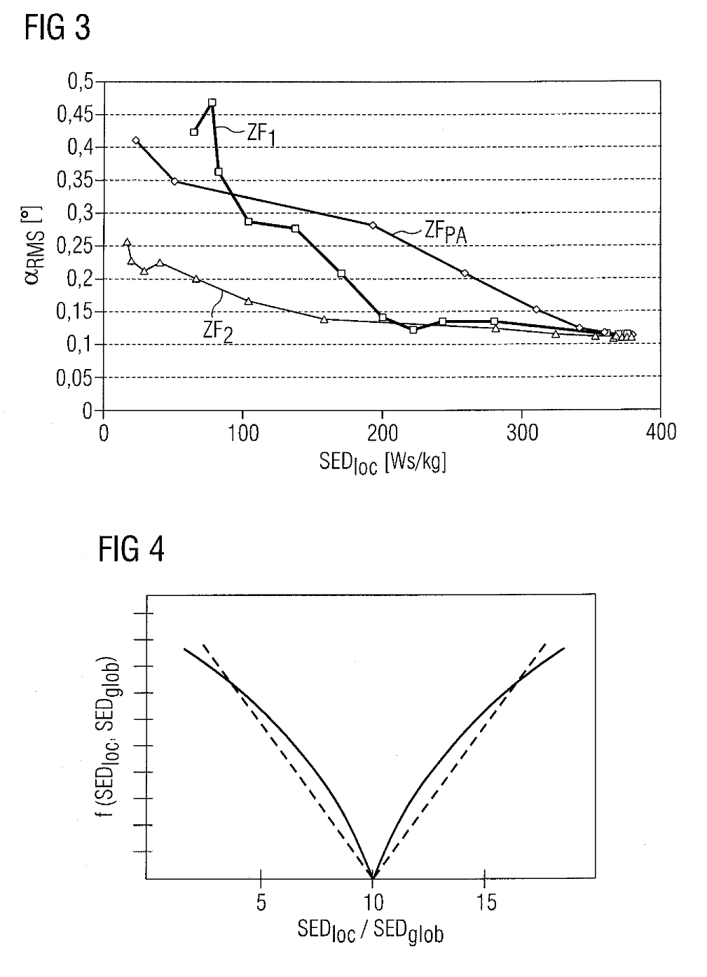

FIG. 3 shows three “L curves” of different target functions, calculated for the homogenization of an 8-channel TX transverse layer of the lower abdomen. The curve ZF_{PA} shows a graph for a target function according to equation (2) with a simple Thikonov regularization. The α_{RMS} value (the root-mean-square deviation of the flip angle α (e.g., the homogeneity of the magnetization)) is plotted against the maximum local SED value.

The curve ZF₁ shows the progression of a target function according to one embodiment:

b=arg_{b}min(∥A·b−m_{target}∥²+γmax²(SED_{loc})) (8)

Instead of minimizing to the simple output power of the radio-frequency pulses, as in the Thikonov regularization, the SAR-critical maximum of the biggest hotspot in the local SED vector is minimized directly through inclusion of the maximum norm of the SED vector SED_{loc} in the target function. A conversion between SAR values and SED values may be achieved (e.g., via the sequence timing).

FIG. 2 shows that in the case of a realistically maximally achievable α_{RMS} value of approximately 0.2°, a local SED exposure of approx. 160 W/kg is reached compared to 280 W/kg with the simple Thikonov regularization. In other words, the local SED exposure has been successfully reduced by almost half.

The curve ZF₂ shows the progression of one embodiment of a target function according to

b=arg_{b}min(∥A·b−m_{target}∥²+γ∥SED_{loc}∥²) (9)

An attempt is made to minimize the square displacement of the entire local SED vector SED_{loc} (e.g., of the local RF exposure vector) to the zero point. In the case of the previously cited value α_{RMS}=0.2°, the local SED value is equal to 70 W/kg (i.e., a quarter of the local SED exposure compared to the method using the simple Thikonov regularization).

However, as already explained above in connection with equation (3), the Thikonov regularization may be included in the target function in addition.

In another embodiment for different target functions, a local exposure function term f(SED_{loc}) that is aimed at optimizing the ratio of the local RF exposure value in relation to a global RF exposure value to a predefined value is chosen. In other words, the local RF exposure function term f(SED_{loc}, SED_{glob}) is dependent not only on the local SED vector SED_{loc}, but also on a global value SED_{glob} (e.g., a global RF exposure value SED_{glob}). The local exposure function term f(SED_{loc}, SED_{glob}) may be configured in different ways. An embodiment is the term:

f(SED_{loc},SED_{glob})=|maxₕ(SED_{loc,h})−η·SED_{glob}∥ (10)

Since the target function according to equation (3) is minimized during the optimization, by including the function term according to equation (10), the difference between the η-fold global RF exposure value SED_{glob} and the maximum of the local RF exposure vector SED_{loc} is automatically minimized. In other words, the ratio of the local RF exposure value (e.g., the maximum of the local RF exposure vector SED_{loc}) to the global RF exposure value SED_{glob} is optimized to a fixed value η.

The global RF exposure value SED_{glob} is defined in the usual way (e.g., the global RF exposure value SED_{glob} is a value, for which limit values already exist or which may be easily converted into a corresponding value).

FIG. 4 shows graphs of two possible local exposure function terms. The function value f(SED_{loc}, SED_{glob}) (in arbitrary units) is plotted in each case against the ratio of the two values SED_{loc}/SED_{glob}. The two possible local exposure function terms are chosen such that a minimum is reached when the ratio SED_{loc}/SED_{glob} lies, for example, at a value of 10. A suitable value for the fixed ratio is dependent on the most disparate conditions and may be dependent on predefined norm values. Such a function may be defined, for example, using two subfunctions to the right and left of the fixedly set ratio.

After act II, a multichannel pulse sequence MP_{L} obtained for the low-flip domain is present at the end of the optimization method. The multichannel pulse sequence MP_{L} is scaled up in act III in order to reach the actually desired target magnetization that may not lie in a flip angle domain of 5°, but goes to a 90° flip angle or more. This is effected through multiplication of the amplitudes of the individual pulses by the desired scaling factor.

In an optional act IV, an error that may occur during the upscaling is corrected using a partial Bloch simulation. The partial Bloch simulation is performed at individual time instants within the pulse sequence. Bloch equations are used for testing data for the respective RF time instant, for which the adjustment is to take place in a simulator, with application of the Bloch equations. The magnetization reached is calculated. Improvements to the specifications of the target magnetization may be discovered, and corresponding minor corrections may be made by modifying the radio-frequency pulse sequences.

In the optional act V, all the found parameters are tested using a temporally complete Bloch simulation. Whether the magnetization reached using the parameters corresponds to the target magnetization is checked.

Both in act TV and in act V, target functions may have a local exposure function term as in act II. In other words, the same target function as in act II may be used.

FIG. 2 shows yet another embodiment, indicated by method act VI, which is linked to method step II in an iterative loop.

With this embodiment, the gradient trajectory GT is specified in act I in a form such that the geometry of the gradient trajectory GT is still variable (e.g., only an initial basic geometry is predefined). As an example, it is assumed in the following that the initially predefined gradient trajectory GT is a spiral in the k-space in an x/y plane. The spiral is defined by the following function:

k=r(t,n₁,n₂)·e^{(-πitn}^{₀}⁾ (11)

In equation (11), r(t, n₁, n₂) is the radius of the spiral at time t, and n₀ is the number of points on the spiral. The two variables n₁ and n₂ are the parameters that may be varied within the scope of the optimization method in order to enable the gradient trajectory to be optimized also in terms of a minimization of the RF exposure for the patient. In the initial basic geometry, the variables n₁ and n₂ may both be set (e.g., equal to 0.33 so that the radius r increases linearly such that the spiral is an Archimedean spiral).

Within an iterative method, in act VI, not just the RF pulses but also the geometry parameters of the gradient trajectory GT are modified. The RF pulses and the geometry parameters of the gradient trajectory GT are included in the actual magnetization m_{actual} in the target function. The RF pulse train b_{c}(t) is calculated for each iteration loop, as described above. The result of the additional iterative adjustment of the gradient parameters is that the target function is not only minimized and hence the optimal RF pulse sequences are found, but the effective radio-frequency power is also reduced.

The geometry of the gradient trajectory GT in the k-space changes over the course of the iteration. The gradient trajectory still has the basic shape of a spiral, for example. The geometry parameters of the spiral are, for example, n₁=0.097 and n₂=0.302. In other words, the spiral covers roughly the same area as prior to the optimization, with the result that the image quality has not changed substantially, but deposits the RF energy at other points. One geometry parameter has been strongly varied automatically in the optimization, whereas the second geometry parameter has remained virtually the same.

After act II, at the end of the optimization method, not only the multichannel pulse sequence MP_{L} obtained for the low-flip domain is available, but an optimized gradient trajectory GT′ is also available.

The above example shows how a reduction in the radio-frequency exposure of the patient by almost a factor of four may be achieved through the use of the method according to the present embodiments. An even greater reduction may be possible by, for example, further varying parameters that may be relevant within the target function.

The use of the indefinite articles “a” or “an” does not preclude the possibility that the features in question may also be present more than once. Similarly, the term “unit” does not exclude the possibility that the unit consists of a plurality of components that, in certain situations, may also be spatially distributed.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for determining a magnetic resonance system control sequence, the magnetic resonance system control sequence comprising a multichannel pulse train having a plurality of individual RF pulse trains that are to be transmitted in parallel by the magnetic resonance system over different independent radio-frequency transmit channels, the method comprising:
calculating the multichannel pulse train in an RF pulse optimization on the basis of a predefined target function with a predefined target magnetization,
wherein the predefined target function includes a local RF exposure value of an examination subject that is dependent on the magnetic resonance control sequence.

2. The method as claimed in claim 1, wherein the local RF exposure value is based on a combination of different local RF exposure values in different volume units.

3. The method as claimed in claim 2, wherein the local RF exposure value includes a predefined norm of a local RF exposure vector.

4. The method as claimed in claim 1, wherein the predefined target function is chosen such that the local RF exposure value is minimized in the optimization.

5. The method as claimed in claim 1, wherein the predefined target function is chosen such that a maximum value of the local RF exposure value is minimized in the optimization.

6. The method as claimed in claim 4, wherein the predefined target function is chosen such that a predefined combination of spatially different local RF exposure values is minimized in the optimization.

7. The method as claimed in claim 1, wherein the predefined target function is dependent on a deviation of the local RF exposure value from a global RF exposure value.

8. The method as claimed in claim 7, wherein the predefined target function is chosen such that a ratio of the local RF exposure value to the global RF exposure value is optimized to a predefined value in the optimization.

9. The method as claimed in claim 1, wherein the local RF exposure value is based on a specific energy dose in at least one volume element.

10. The method as claimed in claim 1, wherein the local RF exposure value is based on a correlation of the plurality of individual RF pulse trains of the multichannel pulse train that are to be transmitted in parallel or on a sensitivity matrix that represents the dependence of RF exposure on a current RF transmission amplitude in a respective volume unit for different volume units of the examination subject.

11. The method as claimed in claim 1, wherein calculating the multichannel pulse train comprises calculating the multichannel pulse train on the basis of a predefined k-space gradient trajectory that is optimized in terms of the local RF exposure value using a parameterizable function in an RF exposure optimization.

12. The method as claimed in claim 11, wherein geometry parameters of the k-space gradient trajectory are varied in the RF exposure optimization.

13. The method as claimed in claim 11, wherein the RF exposure optimization method is linked with the RF pulse optimization.

14. A method for operating a magnetic resonance system, the magnetic resonance system comprising a plurality of independent radio-frequency transmit channels, the method comprising:
obtaining a magnetic resonance control sequence, wherein the magnetic resonance control sequence comprises a multichannel pulse train optimized on the basis of a predefined target function with a predefined target magnetization;
transmitting the multichannel pulse train, the multichannel pulse train having a plurality of individual RF pulse trains, wherein the plurality of individual RF pulse trains is transmitted in parallel by the magnetic resonance system over different independent radio-frequency transmit channels; and
operating the magnetic resonance system using the magnetic resonance control sequence,
wherein the predefined target function is predefined such that the predefined target function includes a local RF exposure value of an examination subject that is dependent on the magnetic resonance control sequence.

15. A control sequence determination device for determining a magnetic resonance system control sequence, the magnetic resonance system control sequence comprising a multichannel pulse train having a plurality of individual RF pulse trains that are to be transmitted in parallel by the magnetic resonance system over different independent radio-frequency transmit channels, the control sequence determination device comprising:
an input interface configured to acquire a target magnetization;
an RF pulse optimization unit configured to calculate the multichannel pulse train on the basis of a predefined target function with a predefined target magnetization in an RF pulse optimization; and
a control sequence output interface,
wherein the control sequence determination device is configured to use the predefined target function, the predefined target function including a local RF exposure value of an examination subject that is dependent on the control sequence in the RF pulse optimization.

16. A magnetic resonance system comprising a plurality of independent radio-frequency transmit channels, the magnetic resonance system comprising:
a gradient system and a control device, the control device being configured for transmitting a multichannel pulse train comprising a plurality of parallel individual RF pulse trains over the plurality of independent radio-frequency transmit channels to perform a desired measurement on the basis of a predefined control sequence; and
a control sequence determination device configured to determine the predefined control sequence and pass the predefined control sequence on to the control device, the control sequence determination device comprising:
an input interface configured to acquire a target magnetization;
an RF pulse optimization unit configured to calculate the multichannel pulse train on the basis of a predefined target function with a predefined target magnetization in an RF pulse optimization; and
a control sequence output interface,
wherein the control sequence determination device is configured to use the predefined target function, the predefined target function including a local RF exposure value of an examination subject that is dependent on the control sequence in the RF pulse optimization.

17. In a non-transitory computer readable medium comprising computer readable instructions that, when executed by a control sequence determination device, cause the control sequence determination device to perform a method for determining a magnetic resonance system control sequence, the instructions comprising:
calculating a multichannel pulse train in an RF pulse optimization on the basis of a predefined target function with a predefined target magnetization; and
transmitting the multichannel pulse train, the multichannel pulse train having a plurality of individual RF pulse trains, wherein the plurality of individual RF pulse trains is transmitted in parallel by the magnetic resonance system over different independent radio-frequency transmit channels,
wherein the predefined target function is predefined such that the predefined target function includes a local RF exposure value of an examination subject that is dependent on the magnetic resonance control sequence.

18. The method as claimed in claim 2, wherein the predefined target function is chosen such that the local RF exposure value is minimized in the optimization method.

19. The method as claimed in claim 4, wherein the predefined target function is chosen such that a maximum value of the local RF exposure value is minimized in the optimization method.

20. The method as claimed in claim 5, wherein the predefined target function is dependent on a deviation of the local RF exposure value from a global RF exposure value.

21. The method as claimed in claim 1 wherein the local RF exposure value comprises a specific energy dose.
